(19) United States
(12) Patent Application Publication
(10) Pub. No.: US 2021/0358852 A1
(43) Pub. Date: Nov. 18, 2021

(54) CIRCUIT SUBSTRATE

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventors: Shungo Hiratani, Yokkaichi-shi, Mie (JP); Shinsuke Okumi, Yokkaichi-shi, Mie (JP); Arinobu Nakamura, Yokkaichi-shi, Mie (JP); Akira Haraguchi, Yokkaichi-shi, Mie (JP); Heng Cao, Yokkaichi-shi, Mie (JP)

(21) Appl. No.: 17/257,132

(22) PCT Filed: Jul. 12, 2019
(86) PCT No.: PCT/JP2019/027776

§ 371 Date: Dec. 30, 2020

(30) Foreign Application Priority Data
Jul. 18, 2018 (JP) 2018-135249

(51) Int. Cl. H01L 23/538; H01L 23/367; H05K 1/02

(52) U.S. Cl. CPC H01L 23/5386; H05K 1/028; H05K 1/0203; H01L 23/367

(57) ABSTRACT

A power circuit is provided with two bus bars in a single plane connected to terminals of a plurality of FETs and includes an insulating region interposed between the bus bars, the power circuit including: a first conductive piece to which one group of the plurality of FETs is fixed; a second conductive piece to which another group of the plurality of FETs is fixed, wherein the plurality of FETs are alternately fixed to the first conductive piece and the second conductive piece.

### CROSS-REFERENCE TO RELATED APPLICATIONS

This application is the U.S. national stage of PCT/JP2019/027776 filed on Jul. 12, 2019, which claims priority of Japanese Patent Application No. JP 2018-135249 filed on Jul. 18, 2018, the contents of which are incorporated herein.

### TECHNICAL FIELD

The present disclosure relates to a circuit substrate.

### BACKGROUND

Conventionally, circuit substrates are commonly known in which substrates on which conduction patterns are formed that are constituted by circuitry that allows a relatively small electrical current to flow are provided with conductive pieces (also referred to as “bus bars”, for example) that constitute circuits for allowing a relatively large electrical current to flow.

JP 2016-220277A discloses an electrical junction box that includes a pair of bus bars, a power semiconductor that is mounted on the pair of bus bars, a control substrate on which a control unit is mounted that controls the power semiconductor, and an FPC that is provided on the upper side of the pair of bus bars and electrically connects the control terminal of the power semiconductor and the control substrate to each other.

Semiconductor elements usually produce heat when conducting an electrical current. Accordingly, it is necessary to appropriately disperse heat and increase the efficiency of heat dissipation in order to avoid problems in the circuit substrate due to the heat produced by the semiconductor elements.

However, in the electrical junction box of JP 2016-220277A, power semiconductor elements (semiconductor elements) are locally concentrated on the bus bars and heat becomes concentrated when conducting an electrical current, and thus the problem described above cannot be solved.

An object of the present disclosure is to provide a circuit substrate with which it is possible to appropriately disperse heat and increase the efficiency of dissipating heat produced by a semiconductor element when conducting electrical current if a plurality of semiconductor elements are used.

### SUMMARY

A circuit substrate according to an aspect of the present disclosure is provided with two conductive pieces in a single plane connected to terminals of a plurality of semiconductor elements, and includes an insulating portion interposed between the conductive pieces, the circuit substrate including: a first conductive piece to which one group of the plurality of semiconductor elements is fixed; a second conductive piece to which another group of the plurality of semiconductor elements is fixed, wherein the plurality of semiconductor elements are alternately fixed to the first conductive piece and the second conductive piece.

First, aspects of the present disclosure will be listed and described. Also, at least portions of the embodiments described below may be freely combined.

A circuit substrate according to an aspect of the present disclosure is provided with two conductive pieces in a single plane connected to terminals of a plurality of semiconductor elements, and includes an insulating portion interposed between the conductive pieces, the circuit substrate including: a first conductive piece to which one group of the plurality of semiconductor elements is fixed; a second conductive piece to which another group of the plurality of semiconductor elements is fixed, wherein the plurality of semiconductor elements are alternately fixed to the first conductive piece and the second conductive piece.

With the present aspect, one group of the plurality of the semiconductor elements is fixed to the first conductive piece, another group of the plurality of semiconductor elements not including the one group of semiconductor elements is fixed to the second conductive piece, and the plurality of semiconductor elements are alternately fixed to the first conductive piece and the second conductive piece.

Accordingly, heat produced by the semiconductor element when conducting electrical current is adequately dispersed to the first conductive piece and the second conductive piece, and the efficiency of heat dissipation is increased.

The circuit substrate according to another aspect of the present disclosure is configured such that the number of semiconductor elements in the one group of semiconductor elements is the same as the number of semiconductor elements in the other group of semiconductor elements.

With the present aspect, the number of semiconductor elements of the one group thereof that are fixed to the first conductive piece is the same as the number of semiconductor elements of the second group thereof that is fixed to the second conductive piece.

Accordingly, heat produced by the plurality of semiconductor elements when conducting electrical current is adequately dispersed to the first conductive piece and the second conductive piece, and the efficiency of heat dissipation is increased.

The circuit substrate according to another aspect of the present disclosure is configured such that the semiconductor elements each include a first terminal and a second terminal that are provided on opposite sides of the bodies of the semiconductor elements, the other group of semiconductor elements include first terminals that are arranged facing the first conductive piece, and the first terminals are connected to the first conductive piece via a conductive first connection sheet, and the one group of semiconductor elements include second terminals that are arranged facing the second conductive piece, and the second terminals are connected to the second conductive piece via a conductive second connection sheet.

With the present aspect, the other group of semiconductor elements includes the first terminals that are positioned on the first conductive piece and connect to the first conductive piece, and the one group of semiconductor elements includes the second terminals that are positioned on the second conductive piece and connect to the second conductive piece.

Accordingly, the length of the first connection sheet that connects the first conductive piece and the first terminals to each other is reduced, and the length of the second connection sheet that connects the second conductive piece and the second terminals to each other is reduced, and it is possible to make the circuit substrate more compact.

The circuit substrate according to another aspect of the present disclosure further includes: a first heat transfer member that is configured to cover the first connection sheet and transfers heat of the first connection sheet to the first conductive piece or the second conductive piece, and a second heat transfer member that is configured to cover the second connection sheet and transfers heat of the second connection sheet to the first conductive piece or the second conductive piece.

With the present aspect, the first heat transfer member transfers the heat of the first connection sheet to the first conductive piece or the second conductive piece, and the second heat transfer member transfers the heat of the second connection sheet to the first conductive piece or the second conductive piece. Accordingly, it is possible to prevent problems arising due to heat in the first connection sheet and the second connection sheet, and it is also possible to disperse the heat of the first connection sheet and the second connection sheet to the first conductive piece or the second conductive piece, and improve the efficiency of heat dissipation.

The circuit substrate according to another aspect of the present disclosure is configured such that the first connection sheet or the second connection sheet is a FPC (Flexible Printed Circuit).

With the present aspect, FPCs are used as the first connection sheet and the second connection sheet. Accordingly, it is possible to simplify the manufacturing process of the circuit substrate.

### Effect of Disclosure

According to the present disclosure, it is possible to appropriately disperse heat and increase the efficiency of dissipating heat that is produced by a semiconductor element when conducting electrical current if a plurality of semiconductor elements are used.

### BRIEF DESCRIPTION OF DRAWINGS

FIG. 1 is a front view of an electrical device according to a present embodiment.

FIG. 2 is an exploded view of a substrate structure of the electrical device according to the present embodiment.

FIG. 3 is a plan view of a substrate structure of the electrical device according to the present embodiment as seen from above.

FIG. 4 is an enlarged view of the vicinity of a plurality of FETs in FIG. 3.

FIG. 5 is a longitudinal sectional view taken along line V-V in FIG. 4.

FIG. 6 is a longitudinal sectional view taken along line IV-IV in FIG. 4.

FIG. 7 is an enlarged view that enlarges and shows the vicinity of the plurality of FETs in a power circuit according to the present embodiment.

### DETAILED DESCRIPTION OF PREFERRED EMBODIMENTS

The present disclosure will be specifically described based on drawings illustrating embodiments of the present disclosure. The circuit substrate according to an embodiment of the present disclosure will be described below with reference to the drawings. Note that the present disclosure is not limited to these examples, but is indicated by the claims and is intended to include all modifications within the meaning and scope of the claims that are equal in meaning and scope to the claims.

The following describes examples of an electrical device that includes the circuit substrate according to the present embodiment.

### First Embodiment

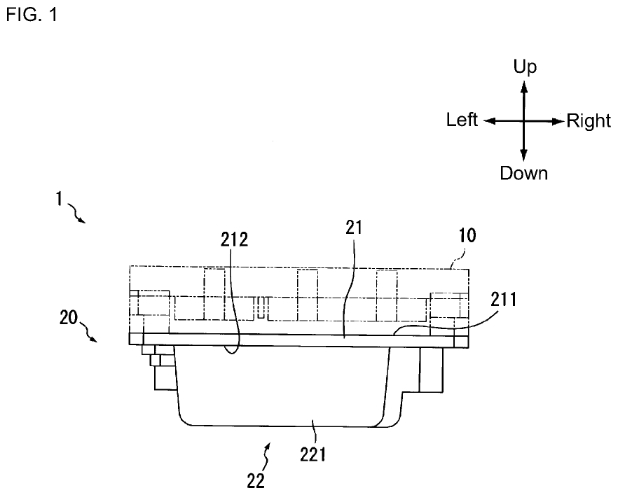

FIG. 1 is a front view of an electrical device 1 according to the present embodiment.

The electrical device 1 constitutes an electrical junction box that is provided in a power supply path between a power source such as a battery included in a vehicle, and a load constituted by an automotive device such as a lamp, a wiper, or the like, or a motor. The electrical device 1 may be used, for example, as an electronic component such as a DC-DC converter or an inverter.

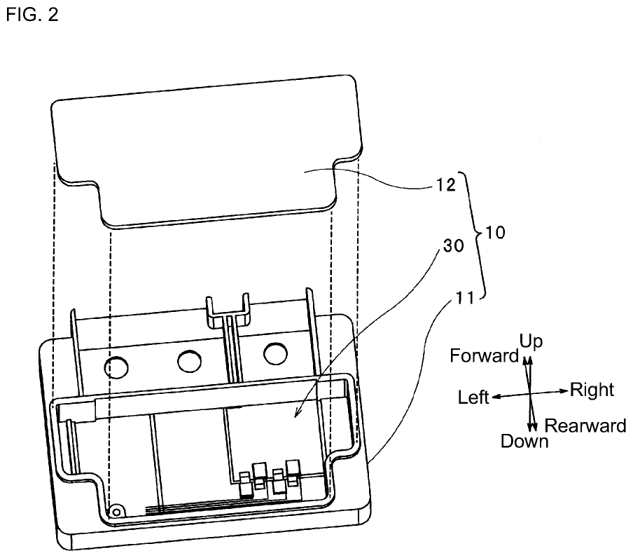

The electrical device 1 includes a substrate structure 10 and a support member 20 that supports the substrate structure 10. FIG. 2 is an exploded view of the substrate structure 10 of the electrical device 1 according to the present embodiment.

In the present embodiment, for the sake of convenience, forward, rearward, left, right, up, and down as shown in FIG. 1 and FIG. 2 define “forward”, “rearward”, “left”, “right”, “up”, and “down” of the electrical device 1. The following description uses the directions of forward, rearward, left, right, up, and down as defined above.

The substrate structure 10 includes a power circuit 30 (circuit substrate) that includes bus bars that constitute a power circuit, semiconductor elements that are mounted on the bus bars, and the like, and the substrate structure 10 also includes a control circuit 12 that turns the power circuit 30 on and off, for example. The semiconductor elements include switching elements such as FETs (Field Effect Transistors) or the like, resistors, coils, or capacitors, all of which are appropriately mounted according to the intended usage of the electrical device 1.

The support member 20 includes a base portion 21 that includes a support surface 211 on the upper surface thereof that supports the substrate structure 10, a heat dissipating portion 22 that is provided on a surface (a lower surface 212) of the support member 20 opposite to the support surface 211, and a plurality of leg portions (not shown) that are provided on the left and right edges of the base portion 21 and sandwich the heat dissipating portion 22. The base portion 21, the heat dissipating portion 22, and the leg portions of the support member 20 are formed as a single piece through die-casting with the use of a metal material such as aluminum, an aluminum alloy, or the like.

The base portion 21 is a rectangular plate member having an appropriate thickness. The substrate structure 10 is fixed to the support surface 211 of the base portion 21 with a commonly-known method such as gluing, screwing, soldering, or the like.

The heat dissipating portion 22 includes a plurality of heat dissipating fins 221 that protrude downward from the lower surface 212 of the base portion 21 and dissipate heat emitted from the substrate structure 10 to the outside thereof. The plurality of heat dissipating fins 221 extend in the left-right direction, and are provided parallel to each other with gaps of a predetermined size provided there-between in the front-rear direction.

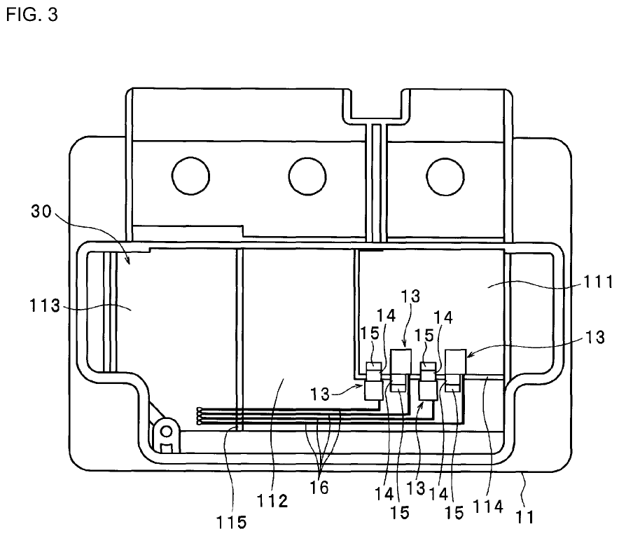

FIG. 3 is a plan view as seen from above the substrate structure 10 of the electrical device 1 according to the present embodiment. For convenience of description, FIG. 3 shows the substrate structure 10 in a state in which the control circuit 12 has been removed.

The substrate structure 10 includes the power circuit 30, the control circuit 12 on which a control circuit is mounted that gives ON/OFF signals to the power circuit 30, and an accommodating portion 11 that accommodates the power circuit 30 and the control circuit 12. The control circuit 12 and the power circuit 30 are provided separate from each other.

The power circuit 30 includes at least the bus bars 111 and 112 (conductive pieces) and a plurality of semiconductor switching elements 13 (semiconductor elements) in which control signals are input from the control circuit 12, and that switches between conduction and non-conduction based on the inputted control signals.

The bus bars 111 and 112 of the power circuit 30 are provided in the same plane, and a substrate portion 113 having a circuit pattern or the like is also provided in the same plane as the bus bars 111 and 112. A first insulating region 114 (insulating portion) is interposed between the bus bar 111 and the bus bar 112, and a second insulating region 115 (insulating portion) is interposed between the bus bar 112 and the substrate portion 113.

The bus bar 111 has a rectangular plate shape, and the bus bar 112 is provided in two areas in the vicinity of the bus bar 111 that are adjacent to each other. The bus bar 112 also has a plate shape similar to that of the bus bar 111. The bus bar 112 is interposed between the substrate portion 113 and the bus bar 111. The bus bar 111 and the bus bar 112 are conductive plate members that are formed from a metal material such as copper, a copper alloy, or the like.

The first insulating region 114 and the second insulating region 115 are insert-molded with the use of an insulating resin material such as, for example, a phenol resin, a glass epoxy resin, or the like. The first insulating region 114 and the second insulating region 115 may also be formed as a single piece with the accommodating portion 11 for example.

The semiconductor switching elements 13 may be FETs (or more specifically surface-mounted power MOSFETs) for example, and are arranged on the bus bar 111 and the bus bar 112. That is to say that in the power circuit 30 according to the present embodiment, the semiconductor switching elements 13 (hereinafter referred to as “FETs 13”) are not arranged straddling the bus bar 111 and the bus bar 112, and are fixed to parts of either the bus bar 111 or the bus bar 112.

The example in FIG. 3 shows four FETs 13 provided along one side of the rectangular bus bar 111, or in other words, provided in parallel along the border (the first insulating region 114) of the bus bar 111 and the bus bar 112.

The bus bar 111 is the bus bar that is directly connected to the drain terminals of the FETs 13, and the bus bar 112 is the bus bar that is directly connected to the source terminals of the FETs 13. Hereinafter, the bus bar 111 and the bus bar 112 may respectively be referred to as a drain bus bar 111 (first conductive piece, second conductive piece) and a source bus bar 112 (second conductive piece, first conductive piece).

Also, in addition to the FETs 13, semiconductor elements such as Zener diodes may also be mounted on the upper side of the bus bars 111 and 112.

Note that for the convenience of description, the example in FIG. 3 shows a configuration in which four FETs 13 are provided parallel with each other along a side area of the drain bus bar 111, but there is no limitation thereto and configurations are also possible in which a plurality of FETs 13 are furthermore provided parallel with each other along another side area of the drain bus bar 111.

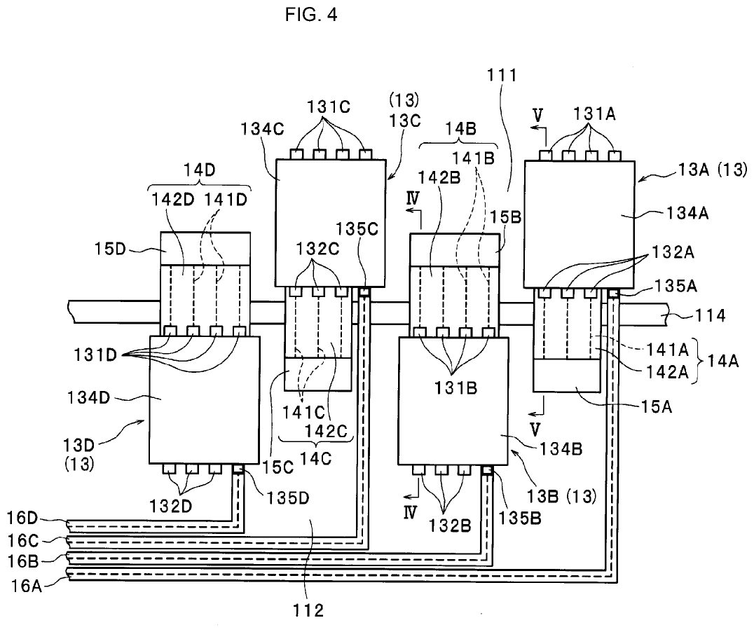

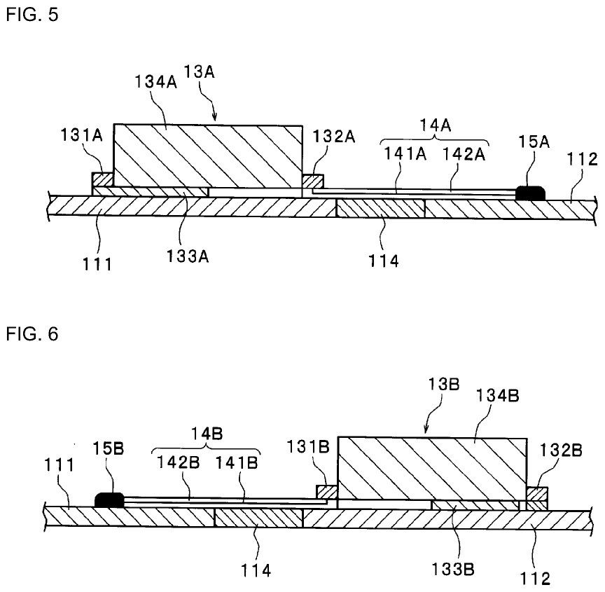

FIG. 4 is an enlarged view of the vicinity of the plurality of FETs 13 in FIG. 3, FIG. 5 is a longitudinal sectional view taken along line V-V in FIG. 4, and FIG. 6 is a longitudinal sectional view taken along line IV-IV in FIG. 4.

In the power circuit 30 according to the present embodiment, four FETs 13, namely an FET 13A, an FET 13B, an FET 13C, and an FET 13D, are provided parallel to each other in that order along the border of the drain bus bar 111 and the source bus bar 112. Hereinafter, the FETs 13A to 13D may also be referred to collectively as the FETs 13.

The FETs 13A to 13D are distributed and arranged on the drain bus bar 111 and the source bus bar 112. More specifically, the FET 13A and the FET 13C (from the one group or the other group of FETs) are fixed to the drain bus bar 111, and the FET 13B and the FET 13D (from the other group or the one group of FETs) are fixed to the source bus bar 112. That is to say that the same number of the FETs 13 are fixed to the drain bus bar 111 and the source bus bar 112.

More specifically, the FETs 13A to 13D are alternately fixed to the drain bus bar 111 and the source bus bar 112. That is to say that the FET 13A is fixed to the drain bus bar 111, the FET 13B is fixed to the source bus bar 112, the FET 13C is fixed to the drain bus bar 111, and the FET 13D is fixed to the bus bar 112.

The FETs 13A and 13C are electrically connected to the bus bars 111 and 112 in the same way, and the FETs 13B and 13D are electrically connected to the bus bars 111 and 112 in the same way. The way that the FETs 13A and 13C are connected to the bus bars 111 and 112 is different to the way that the FETs 13B and 13D are connected to the bus bars 111 and 112.

Accordingly, hereinafter, only the FET 13A will be described in regards to the FET 13A and the FET 13C, only the FET 13B will be described in regards to the FET 13B and the FET 13D, and descriptions of the FET 13C and the FET 13D will be omitted.

The FET 13A includes an element body 134A, and four drain terminals 131A (first terminal, second terminal) and three source terminals 132A (second terminal, first terminal) that are provided on opposite sides of the FET 13A and sandwich the element body 134A. For example, one side surface of the element body 134A is provided with the drain terminals 131A, and another side surface of the element body 134A opposite to the one side surface is provided with the source terminals 132A. Also, the FET 13A includes a gate terminal 135A, and for example the gate terminal 135A may be provided in the vicinity of the source terminals 132A. However, the position of the gate terminal 135A is not limited to the configuration described above.

The FET 13A is fixed to the drain bus bar 111 by soldering. That is to say that a solder fixing portion 133A is interposed between the bottom surface of the FET 13A and the drain bus bar 111. The solder fixing portion 133A solders at least a portion of the bottom surface of the FET 13A to the drain bus bar 111.

The drain terminals 131A of the FET 13A is soldered and connected to the solder fixing portion 133A and is electrically connected to the drain bus bar 111 via the solder fixing portion 133A. That is to say that the drain terminals 131A are directly electrically connected to the drain bus bar 111.

On the other hand, the source terminals 132A of the FET 13A are arranged facing the source bus bar 112, or in other words the source terminals 132A are arranged facing the first insulating region 114. Also, the source terminals 132A are electrically connected to the source bus bar 112, which is on the opposite side of the first insulating region 114 to the source terminals 132A, via the connection sheet 14A (first connection sheet, second connection sheet). That is to say that the connection sheet 14A is provided over the bus bars 111 and 112 so as to straddle the first insulating region 114.

The connection sheet 14A includes a line-shaped conductive portion 141A (shown as a broken line in FIG. 4) that electrically connects the source terminals 132A and the source bus bar 112 to each other, and an insulating portion 142A that insulates the conductive portion 141A from the drain bus bar 111. One end of the conductive portion 141A is soldered and connected to the source terminals 132A, and the other end of the conductive portion 141A is soldered and connected to the source bus bar 112. That is to say that the other end of the connection sheet 14A is connected to the source bus bar 112 via a solder-connection portion 15A.

In this way, the FET 13A is arranged such that the source terminals 132A thereof face the source bus bar 112, and therefore it is possible to shorten the length of the connection sheet 14A and it is possible to simplify the structure of the power circuit 30 according to the present embodiment, in comparison to a configuration in which the source terminals 132A do not face the source bus bar 112.

On the other hand, the FET 13B includes an element body 134B, and four drain terminals 131B (first terminal, second terminal) and three source terminals 132B (second terminal, first terminal) that are provided on opposite sides of the FET 13B to each other and sandwich the element body 134B. For example, one side surface of the element body 134B is provided with the drain terminals 131B, and another side surface of the element body 134B opposite to the one side surface thereof is provided with the source terminals 132B. Also, the FET 13B includes a gate terminal 135B, and for example the gate terminal 135B may be provided in the vicinity of the source terminals 132B.

The FET 13B is fixed to the source bus bar 112 by soldering. That is to say that a solder fixing portion 133B is interposed between the bottom surface of the FET 13B and the source bus bar 112. The solder fixing portion 133B solders at least a portion of the bottom surface of the FET 13B to the source bus bar 112.

For example, the source terminals 132B of the FET 13B may be electrically connected to the source bus bar 112 by a soldered connection. That is to say that the source terminals 132B are directly electrically connected to the source bus bar 112.

On the other hand, the drain terminals 131B of the FET 13B are arranged facing the drain bus bar 111, or in other words the drain terminals 131B are arranged facing the first insulating region 114. Also, the drain terminals 131B are electrically connected to the drain bus bar 111, which is on the opposite side of the first insulating region 114 to the drain terminals 131B, via a connection sheet 14B (second connection sheet, first connection sheet).

The connection sheet 14B includes a line-shaped conductive portion 141B (shown as a broken line in FIG. 4) that electrically connects the drain terminals 131B and the drain bus bar 111 to each other, and an insulating portion 142B that insulates the conductive portion 141B from the source bus bar 112. One end of the conductive portion 141B is soldered and connected to the drain terminals 131B, and the other end of the conductive portion 141B is soldered and connected to the drain bus bar 111. That is to say that the other end of the connection sheet 14B is connected to the drain bus bar 111 via a solder-connection portion 15B.

In this way, the FET 13B are arranged such that the drain terminals 131B thereof face the drain bus bar 111, and therefore it is possible to shorten the length of the connection sheet 14B and it is possible to simplify the structure of the power circuit 30 according to the present embodiment, in comparison to a configuration in which the drain terminals 131B do not face the drain bus bar 111.

For example, the conductive portions 141A and 141B may be made from a copper foil, the insulating portions 142A and 142B may be made from resin sheets, and the conductive portions 141A and 141B may be embedded inside of the insulating portions 142A and 142B. The connection sheets 14A and 14B may also be FPCs, (Flexible Printed Circuits), for example.

Also, there is no limitation to the configurations described above, and the conductive portions 141A and 141B may also be attached to the top of the insulating portions 142A and 142B.

Note that the connection sheets 14A and 14B may also be partially fixed to the bus bars 111 and 112 or to the first insulating region 114. That is to say that the connection sheets 14A and 14B may be fixed to the bus bars 111 and 112 or to the first insulating region 114 at a single location or at a plurality of locations. In this case, it is possible that a certain amount of deformation may occur in the connection sheets 14A and 14B in the length direction thereof (the direction in which the conductive portions 141A and 141B extend). Accordingly, the connection sheets 14A and 14B may deform when heat is produced by the FETs 13A and 13B due to the drain terminals 131A and 131B or the source terminals 132A and 132B thermally expanding and/or contracting.

The gate terminal 135A of the FET 13A is electrically connected via a distant connection sheet 16A to the substrate portion 113 that is more distant from the gate terminal 135A than the source bus bar 112 is. The distant connection sheet 16A is provided on the bus bars 111 and 112, and extends from the bus bar 111, over the bus bar 112, and to the substrate portion 113.

Also, a gate terminal 135B of the FET 13B is electrically connected to the distant substrate portion 113 via a distant connection sheet 16B. The distant connection sheet 16B is provided on the source bus bar 112.

The substrate portion 113 may, for example, include an insulated substrate, and may include a control circuit (not shown) that includes a semiconductor element such as a resistor, a coil, a capacitor, a diode, or the like mounted on an upper surface of the insulating substrate, and may also be provided with a circuit pattern that electrically connects the semiconductor elements.

As described above, in the power circuit 30 according to the present embodiment, some of the FETs 13A to 13D are fixed to the drain bus bar 111 and some are connected to the source bus bar 112. Accordingly, heat produced by the FETs 13A to 13D when conducting electrical current is dispersed without being concentrated in any one part of the drain bus bar 111 or the source bus bar 112. Accordingly, it is possible to prevent problems arising due to the concentration of heat, and it is possible to increase the efficiency of heat dissipation in the power circuit 30.

Also, in the power circuit 30 according to the present embodiment, the FETs 13A to 13D are alternately fixed to the drain bus bar 111 and the source bus bar 112. Accordingly, gaps occur between the FET 13A and 13C on the drain bus bar 111, and between the FET 13B and 13D on the source bus bar 112. Thus, heat produced by the FETs 13A to 13D when conducting electrical current is widely dispersed without being locally concentrated in the drain bus bar 111 or the source bus bar 112. Accordingly, it is possible to increase the efficiency of heat dissipation in the power circuit 30.

Furthermore, the FETs 13A to 13D are fixed to the drain bus bar 111 or the source bus bar 112, and therefore heat that is produced by the FETs 13A to 13D when conducting electrical current is transferred to the drain bus bar 111 or the source bus bar 112. Accordingly, it is possible to prevent problems arising in the FETs 13A to 13D that occur due to the heat produced by the FETs 13A to 13D.

### Second Embodiment

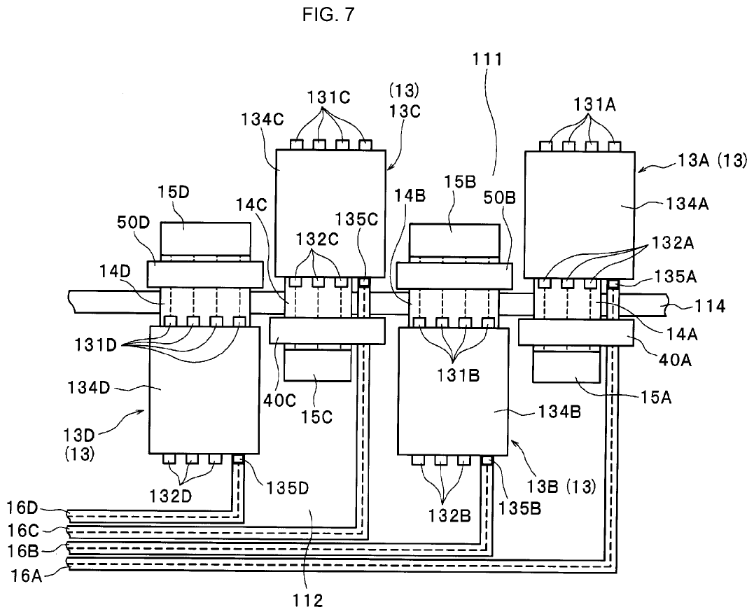

FIG. 7 is an enlarged view that enlarges and shows the vicinity of the plurality of FETs 13 in the power circuit 30 according to the embodiment.

In the power circuit 30 according to the present embodiment, similar to the first embodiment, four FETs 13, namely the FET 13A, the FET 13B, the FET 13C, and the FET 13D, are provided parallel to each other in that order along the border of the drain bus bar 111 and the source bus bar 112.

The FETs 13A to 13D are alternately fixed to the drain bus bar 111 and the source bus bar 112, and the FET 13A and the FET 13C (from the one group and other group of FETs, respectively) are fixed to the drain bus bar 111, and the FET 13B and the FET 13D (from the other group and the one group of FETs, respectively) are fixed to the source bus bar 112.

That is to say that the FET 13A is fixed to the drain bus bar 111, the FET 13B is fixed to the source bus bar 112, the FET 13C is fixed to the drain bus bar 111, and the FET 13D is fixed to the bus bar 112.

The structure of the FETs 13A to 13D and the way the FETs 13A to 13D and the bus bars 111 and 112 are electrically connected to each other is described in the first embodiment, and thus detailed descriptions thereof will be omitted.

In the power circuit 30 according to the present embodiment, the FETs 13A and 13C respectively include first heat transfer members 40A and 40C (first heat transfer member, second heat transfer member), and the FETs 13B and 13D respectively include second heat transfer members 50B and 50D (second heat transfer member, first heat transfer member).

The first heat transfer members 40A and 40C respectively cover portions of the connection sheets 14A and 14C, and the source bus bar 112 in the vicinity of the covered portions of the connection sheets 14A and 14C. That is to say that the first heat transfer members 40A and 40C are in contact with both the connection sheets 14A and 14C and the source bus bar 112. Accordingly, heat produced by the connection sheets 14A and 14C can be transferred to the source bus bar 112.

Also, the second heat transfer members 50B and 50D respectively cover portions of the connection sheets 14B and 14D, and the drain bus bar 111 in the vicinity of the covered portions of the connection sheets 14B and 14D. That is to say that the second heat transfer members 50B and 50D are in contact with both the connection sheets 14B and 14D and the drain bus bar 111. Accordingly, heat produced by the connection sheets 14B and 14D can be transferred to the drain bus bar 111.

The first heat transfer members 40A and 40C and the second heat transfer members 50B and 50D may be made from a material having excellent thermal conductivity such as acrylic, silicon, polyophyllene, and the like.

In the following description, the first heat transfer members 40A and 40C may also be referred to as a first heat transfer member 40, and the second heat transfer members 50B and 50D may also be referred to as a second heat transfer member 50.

As described above, the power circuit 30 according to the present embodiment includes the first heat transfer member 40 and the second heat transfer member 50, and therefore heat produced in the connection sheets 14A to 14D is dispersed and air-cooled by being transferred to the drain bus bar 111 or the source bus bar 112. Accordingly, it is possible to increase the efficiency of heat dissipation in the power circuit 30.

Components that are similar to those in the first embodiment are given the same reference numerals and detailed descriptions thereof are omitted.

The embodiments disclosed herein are illustrative in all respects and should not be considered restrictive. The scope of the disclosure is indicated by the claims, not by the meanings described above, and is intended to include all changes within the meaning and scope of the claims that are equal to the claims.

1. A circuit substrate that is provided with two conductive pieces in a single plane connected to terminals of a plurality of semiconductor elements, and that includes an insulating portion interposed between the conductive pieces, the circuit substrate comprising:
a first conductive piece to which one group of the plurality of semiconductor elements is fixed;
a second conductive piece to which another group of the plurality of semiconductor elements is fixed, wherein
the plurality of semiconductor elements are alternately fixed to the first conductive piece and the second conductive piece.

2. The circuit substrate according to claim 1, wherein the number of semiconductor elements in the one group of semiconductor elements is the same as the number of semiconductor elements in the other group of semiconductor elements.

3. The circuit substrate according to claim 1, wherein the semiconductor elements each include a first terminal and a second terminal that are provided on opposite sides of the bodies of the semiconductor elements,
the other group of semiconductor elements include first terminals that are arranged facing the first conductive piece, and the first terminals are connected to the first conductive piece via a conductive first connection sheet, and
the one group of semiconductor elements include second terminals that are arranged facing the second conductive piece, and the second terminals are connected to the second conductive piece via a conductive second connection sheet.

4. The circuit substrate according to claim 3, further comprising:
a first heat transfer member that is configured to cover the first connection sheet and transfers heat of the first connection sheet to the first conductive piece or the second conductive piece, and
a second heat transfer member that is configured to cover the second connection sheet and transfers heat of the second connection sheet to the first conductive piece or the second conductive piece.

5. The circuit substrate according to claim 3, wherein the first connection sheet or the second connection sheet is a FPC (Flexible Printed Circuit).

6. The circuit substrate according to claim 2, wherein the semiconductor elements each include a first terminal and a second terminal that are provided on opposite sides of the bodies of the semiconductor elements,
the other group of semiconductor elements include first terminals that are arranged facing the first conductive piece, and the first terminals are connected to the first conductive piece via a conductive first connection sheet, and
the one group of semiconductor elements include second terminals that are arranged facing the second conductive piece, and the second terminals are connected to the second conductive piece via a conductive second connection sheet.

7. The circuit substrate according to claim 4, wherein the first connection sheet or the second connection sheet is a FPC (Flexible Printed Circuit).
